(19) United States
(12) Patent Application Publication
(10) Pub. No.: US 2006/0014350 A1
(43) Pub. Date: Jan. 19, 2006

(54) METHOD FOR FABRICATING A SEMICONDUCTOR TRANSISTOR DEVICE HAVING ULTRA-SHALLOW SOURCE/DRAIN EXTENSIONS

(76) Inventors: Yun-Ren Wang, Tai-Nan City (TW); Ying-Wei Yen, Miao- Li Hsien (TW); Shu-Yen Chan, Hsin-Chu Hsien (TW)

Correspondence Address: NORTH AMERICA INTELLECTUAL PROPERTY CORPORATION, P.O. BOX 506, MERRIFIELD, VA, 22116, US

(21) Appl. No.: 10/710,521

(22) Filed: Jul. 18, 2004

(51) Int. Cl. H01L 21/336; H01L 21/331; H01L 21/425

(52) U.S. Cl. 438/293; 438/514; 438/353

(57) ABSTRACT

A method for fabricating a semiconductor transistor device having ultra-shallow source/drain extensions is provided. A silicon substrate having thereon a poly gate structure is prepared. The poly gate structure has sidewalls and a top surface. An offset spacer is formed on its sidewall. An ion implantation process is carried out to form an ultra-shallow junction doping region in the silicon substrate next to the offset spacer. An oxide liner is deposited on the offset spacer and on the top surface of the poly gate structure. A tensile nitride spacer layer is then deposited on the oxide liner. A stress modification implantation process is performed to turn the tensile nitride spacer layer into a more compressive status. A dry etching process is then carried out to etch the nitride spacer layer so as to form a spacer.

### BACKGROUND OF INVENTION

1. Field of the Invention

The present invention generally relates to semiconductor processes, and more particularly, to a method for fabricating a semiconductor transistor device having ultra-shallow source/drain extensions, which is capable of retarding silicon defect-induced transient enhanced diffusion (TED) effect.

2. Description of the Prior Art

Continued device scaling demands that source/drain (S/D) junctions of MOS transistor devices become thinner and thinner to avoid short channel effect. However, the prior art MOS structure has a drawback in that the shallower the S/D extension is, the greater the sheet resistance occurs in operation. As known to those skilled in the art, large sheet resistance leads to insufficient saturation currents. The situation becomes worse when the MOS device is a PMOS device. As silicon devices are continuously scaled to smaller sizes, there is an ever demand to reduce the diffusion of dopants. Diffusion mechanism and electrical activation of implanted dopant species such as B⁺, P⁺, and As⁺ dopants in crystalline Si are becoming essential to the fabrication of advanced nano-scale transistor devices.

Current methods for forming ultra-shallow junctions in the source and drain regions of complementary metal-oxide semiconductor (CMOS) transistor circuits use low energy ion implantation and rapid thermal annealing (RTA). Spike annealing, with fast ramping and short dwell time at maximum temperature, has been shown to be advantageous for shallow junction formation. During annealing, the implanted dopants such as boron experience an enhanced diffusion when excess Si interstitials are present. For implanted dopant species excess Si interstitials evolve from the residual implant damage until the damage is annealed out. The resulting enhanced diffusion is thus transient and is denoted transient-enhanced diffusion, or TED, which adversely affects the performance of the transistor devices. It is generally accepted that boron diffuses primarily via an interstitial mechanism and boron diffusivity is, therefore, dependent on the silicon interstitial concentration.

In most cases, ultra-shallow source/drain extensions having low sheet resistance and abrupt junction profile are desired in terms of device's performance. Accordingly, there is a need in this industry to provide a method for fabricating a semiconductor transistor device having ultra-shallow source/drain extensions, which is capable of retarding silicon defect-induced transient enhanced diffusion (TED) effect, and thus reducing sheet resistance of the ultra-shallow source/drain extensions.

### SUMMARY OF INVENTION

It is therefore the primary object of the present invention to provide a semiconductor process for eliminating or retarding the above-described silicon defect-induced transient enhanced diffusion effects.

It is another object of the present invention to provide a method for fabricating a semiconductor transistor device having ultra-shallow source/drain extensions, which is capable of retarding silicon defect-induced transient enhanced diffusion (TED) effect, and thus reducing sheet resistance of the ultra-shallow source/drain extensions.

It is still another object of the present invention to provide a method for fabricating a semiconductor transistor device having ultra-shallow source/drain extensions by utilizing a spacer layer having compressive residual stress.

According to the claimed invention, a method for fabricating a semiconductor transistor device having ultra-shallow source/drain extensions is provided. A silicon substrate having thereon a poly gate structure is prepared. The poly gate structure has sidewalls and a top surface. An offset spacer is formed on its sidewall. An ion implantation process is carried out to form an ultra-shallow junction doping region in the silicon substrate next to the offset spacer. An oxide liner is deposited on the offset spacer and on the top surface of the poly gate structure. A tensile nitride spacer layer is then deposited on the oxide liner. A stress modification implantation process is performed to turn the tensile nitride spacer layer into a less tensile stress status, or even into a compressive stress status. A dry etching process is then carried out to etch the nitride spacer layer so as to form a spacer.

Other objects, advantages, and novel features of the claimed invention will become more clearly and readily apparent from the following detailed description when taken in conjunction with the accompanying drawings.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 to FIG. 3 are schematic cross-sectional diagrams illustrating several intermediate steps for forming a PMOS field effect transistor device having ultra-shallow source/drain extensions in accordance with one preferred embodiment of this invention;

FIG. 4 demonstrates a table listing preferred parameters of the stress modification implantation process using respective germanium and xenon as dopant; and

FIG. 5 is a table listing changes to the stress of the nitride spacer layer and the sheet resistance (Rs) of the ultra-shallow source/drain extensions under different doping conditions when using germanium (Ge) as dopant during the stress modification implantation process.

### DETAILED DESCRIPTION

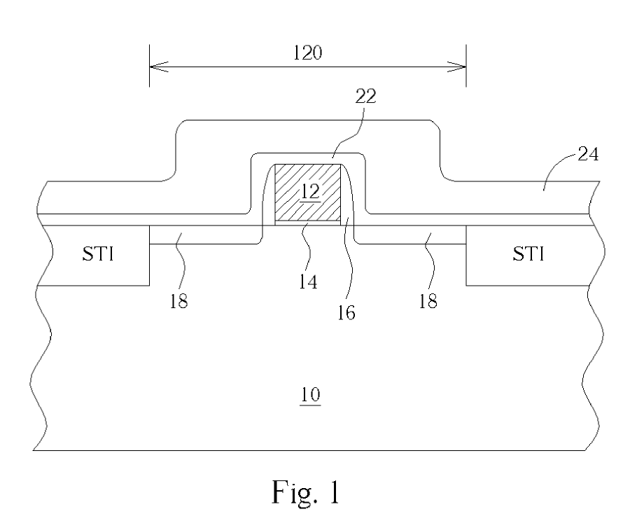

Please refer to FIG. 1 to FIG. 3. FIG. 1 to FIG. 3 are schematic cross-sectional diagrams illustrating several intermediate steps for forming a PMOS field effect transistor device 100 having ultra-shallow source/drain extensions 18 in accordance with one preferred embodiment of this invention. As shown in FIG. 1, an N type doped silicon substrate 10 is prepared. An exemplary active area 120 is defined by shallow trench isolation (STI) region. A poly gate structure 12 is formed on the active area 120. A gate dielectric such as silicon dioxide is interposed between the poly gate structure 12 and the silicon substrate 10.

An offset spacer 16 is formed on each sidewall of the poly gate structure 12. The offset spacer 16 is typically made of silicon dioxide, but not limited thereto. After the formation of the offset spacer 16, a low-energy ion implantation is performed to implant P type dopants such as boron into the silicon substrate 10 adjacent to the poly gate structure 12, thereby forming P type doping regions 18 having an ultra shallow junction. According to the preferred embodiment, the P type doping regions 18 has a junction depth that is less then 30 angstroms.

Subsequently, a chemical vapor deposition (CVD) process or silicon oxide forming process using a furnace system is carried out to form a silicon dioxide liner 22 on the poly gate structure 12 and also on the P type doping regions 18. Preferably, the silicon dioxide liner 22 may use bis(tertiarybutylamine)silane (BTBAS) as a precursor.

A silicon nitride spacer layer 24 is then deposited on the silicon dioxide liner 22 using methods known in the art, for example, CVD methods. According to the preferred embodiment, the silicon nitride spacer layer 24 has a thickness of about 600˜700 angstroms. At this phase, the silicon nitride spacer layer 24 has a tensile residual stress.

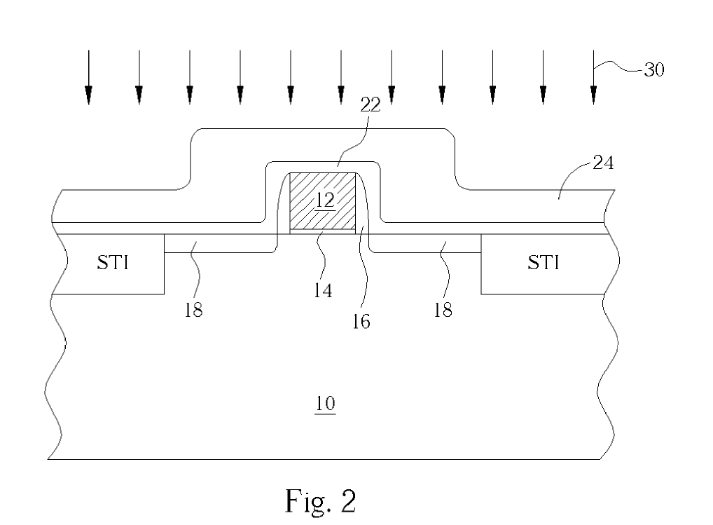

As shown in FIG. 2, a stress modification implantation process 30 is carried out to alter the stress status inside the silicon nitride spacer layer 24. Preferably, dopant species that is electrically neutral and has a heavier atomic weight are used, for example, germanium or xenon. The preferred implantation energy of the stress modification implantation process 30 ranges between 25 and 150 KeV and the preferred dose of the stress modification implantation process 30 ranges between 2E14 and 5E15 atoms/cm². After performing the stress modification implantation process, the implanted silicon nitride spacer layer 24 is turned into a less tensile status, or even into a completely compressive status.

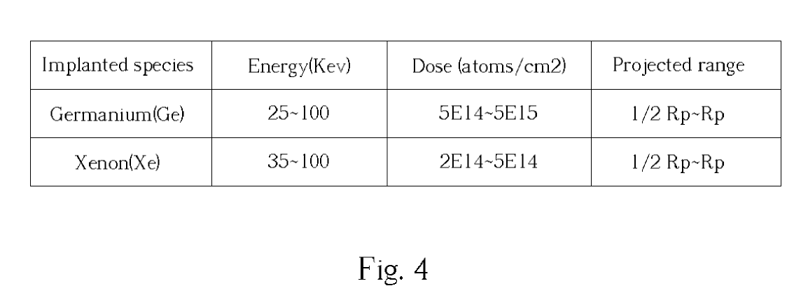

In accordance with the preferred embodiment, the stress modification implantation process 30 has a projected range (Rp) that is preferably smaller than the thickness of the silicon nitride spacer layer 24. By way of example, in a case that the thickness of the silicon nitride spacer layer 24 is about 700 angstroms, the projected range (Rp) of the stress modification implantation process 30 preferably ranges between 350 and 700 angstroms. FIG. 4 demonstrates a table listing preferred parameters of the stress modification implantation process using respective germanium and xenon as dopant.

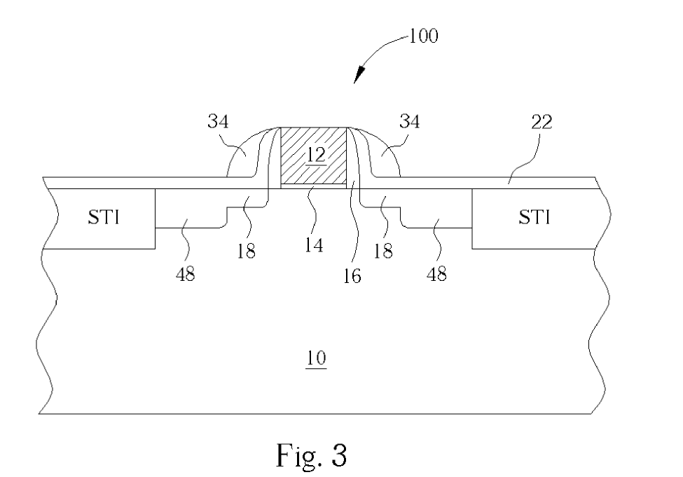

As shown in FIG. 3, a dry etching process is performed to etch the silicon nitride spacer layer 24 so as to form a spacer 34 on each sidewall of the poly gate structure 12. Thereafter, an ion implantation process is carried out to implant P type dopants into the silicon substrate 10 adjacent to the spacer 34, thereby forming source/drain regions 48 of the PMOS transistor device 100.

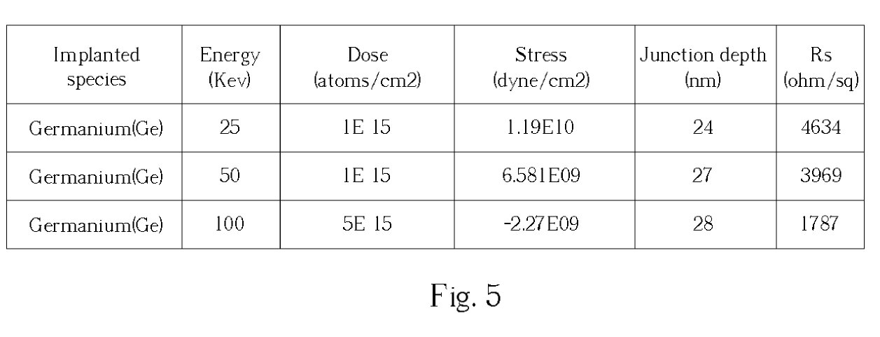

FIG. 5 is a table listing changes to the stress of the silicon nitride spacer layer 24 and the sheet resistance (Rs) of the ultra-shallow source/drain extensions 18 under different doping conditions when using germanium (Ge) as dopant during the stress modification implantation process. As indicated, when a Ge implantation energy of 100 KeV and a implant dose of about 5E15 atoms/cm² are used, the stress of the silicon nitride spacer layer 24 decreases from 1.19E10 dyne/cm² (tensile) down to −2.27E9 dyne/cm² (compressive), resulting in significant decrease of the sheet resistance of the ultra shallow junction doping regions from 4634 ohm/sq down to 1787 ohm/sq.

It is believed that the stress modification implantation process of the present invention is capable of reducing vacancy defects in the silicon surface because the stress status of the silicon nitride spacer layer 24 is altered from a tensile state to a compressive state. The defect-induced boron transient diffusion is thus alleviated. Hence, relative low sheet resistance and abrupt junction profile of the ultra-shallow source/drain extensions 18 are obtained.

Those skilled in the art will readily observe that numerous modifications and alterations of the present invention method may be made while retaining the teachings of the invention. Accordingly, the above disclosure should be construed as limited only by the metes and bounds of the appended claims.

What is claimed is:

1. A method for fabricating a semiconductor transistor device having ultra-shallow source/drain extensions, comprising:
preparing a substrate;
forming a gate structure on said substrate, the gate structure having sidewalls and a top surface;
forming an offset spacer on each said sidewall of said gate structure;
ion implanting said substrate next to said gate structure to form shallow-junction doping regions;
depositing a spacer liner on said offset spacer and on said top surface of said gate structure;
depositing a spacer layer on said spacer liner;
performing a stress modification implantation process to alter said spacer layer from a tensile status to a less tensile status, or into a compressive status; and
dry etching said spacer layer to form spacers.

2. The method according to claim 1 wherein said substrate is a silicon substrate.

3. The method according to claim 1 wherein said gate structure is a poly gate structure.

4. The method according to claim 1 wherein a gate dielectric is interposed between said gate structure and said substrate.

5. The method according to claim 1 wherein said spacer layer is made of silicon nitride.

6. The method according to claim 1 wherein said stress modification implantation process uses germanium or xenon as dopants.

7. The method according to claim 1 wherein said stress modification implantation process uses dopant species, which are electrically neutral.

8. The method according to claim 1 wherein said stress modification implantation process is carried out in an energy range of about 25 to 150 KeV.

9. The method according to claim 1 wherein said stress modification implantation process is carried out using germanium as a dopant at an implant energy of about 100 KeV and an implant dose of about 5E15 atoms/cm².

10. The method according to claim 1 wherein said shallow-junction doping regions are P type doped.

11. A method for fabricating a semiconductor transistor device, comprising:
providing a silicon substrate;
forming a gate structure on said silicon substrate, the gate structure having sidewalls and a top surface;
forming an offset spacer on each said sidewall of said gate structure;
performing a first ion implantation to implant said silicon substrate next to said gate structure so as to form first doping regions acting as a source/drain extensions of said semiconductor transistor device;
depositing a spacer liner on said offset spacer, on said top surface of said gate structure, and on said first doping regions;
depositing a spacer layer on said spacer liner;
performing a stress modification implantation process to alter said spacer layer from a tensile status to a less tensile status, or into a compressive status;
dry etching said spacer layer to form spacers; and performing a second ion implantation to implant said silicon substrate next to said spacer so as to form second doping regions acting as a source/drain of said semiconductor transistor device.

12. The method according to claim 11 wherein said stress modification implantation process uses dopant species, which are electrically neutral.

13. The method according to claim 11 wherein said stress modification implantation process uses germanium or xenon as dopants.

14. The method according to claim 11 wherein said stress modification implantation process is carried out in an energy range of about 25 to 150 KeV.

15. The method according to claim 11 wherein said stress modification implantation process is carried out using germanium as a dopant, at an implant energy of about 100 KeV and an implant dose of about 5E15 atoms/cm².

16. The method according to claim 11 wherein said stress modification implantation process has a projected range (Rp) that is smaller than said spacer layer's thickness.

17. The method according to claim 16 wherein said spacer layers thickness is about 600˜700 angstroms.

18. The method according to claim 11 wherein said spacer layer is made of silicon nitride.

19. The method according to claim 11 wherein a gate dielectric is interposed between said gate structure and said substrate.

20. The method according to claim 11 wherein said stress modification implantation process reduces vacancy defects of said silicon substrate.
